(19) United States
(12) Patent Application Publication
(10) Pub. No.: US 2026/0106106 A1
(43) Pub. Date: Apr. 16, 2026

(54) Analysis System and Particle Analysis Method

(71) Applicant: HITACHI HIGH-TECH CORPORATION, Minato-ku, Tokyo (JP)

(72) Inventors: Maasa HIGASHIMATA, Tokyo (JP); Toru AISO, Tokyo (JP); Masanari FURIKI, Tokyo (JP); Megumi NAKAMURA, Tokyo (JP)

(21) Appl. No.: 19/116,496

(22) PCT Filed: Oct. 24, 2022
(86) PCT No.: PCT/JP2022/039526

§ 371 Date: Mar. 28, 2025

(51) Int. Cl. H01J 37/28; G01B 9/02091; G01B 11/00; G01B 11/06; G01N 15/10; G01N 15/14; G01N 15/1433; G01N 15/149

(52) U.S. Cl. CPC H01J 37/28; G01B 9/02091; G01B 11/002; G01B 11/0608; G01N 15/1427; G01N 15/1433; G01N 15/149; G01N 2015/1028; G01N 2015/1029; G01N 2015/1488; G01N 2015/1493; H01J 2237/2815

(57) ABSTRACT

An analysis system and a particle analysis method capable of measuring a height of particles with high accuracy are provided.

The analysis system includes: an SEM apparatus 10 that captures an image of each particle contained in a sample as an SEM image and observes a two-dimensional shape of each particle included in the SEM image; a CSI apparatus 20 that captures an image of each particle contained in the sample as a CSI image and measures a height of each particle included in the CSI image; and a controller that controls the SEM apparatus and the CSI apparatus. The controller captures the SEM image using the SEM apparatus 10, classifies each particle included in the SEM image by size determined based on the imaging magnification of the CSI apparatus 20, and captures the CSI image of each particle in the particle group using the CSI apparatus 20 for each classified particle group.

### TECHNICAL FIELD

The present invention relates to an analysis system and a particle analysis method. For example, the present invention relates to a combined analysis technique of microparticles using a scanning white-light interference microscope, that is, a coherence scanning interferometry (CSI), and an electron microscope, that is, a scanning electron microscope (SEM), and a linkage technique of position coordinates between CSI and SEM.

### BACKGROUND ART

In a process of manufacturing lithium ion batteries and fuel cells, entry of foreign particles such as metal reduces reliability of the battery. For example, a sharp tip of the entered foreign particles may tear a separator, causing an internal short-circuit. To ensure the quality of the battery, in addition to two-dimensional shape observation and elemental analysis of the foreign particles, three-dimensional combined analysis including height measurement is also necessary.

In the combined analysis of particles, there is a known method using a compound microscope device that combines a confocal microscope and an SEM, as shown in PTL 1. When the technology of PTL 1 is used, coordinate systems of the confocal microscope and the SEM are shared, and thus, respective fields of view can be precisely aligned. Therefore, three-dimensional combined analysis of particles can be performed by combining two-dimensional color information and height information of a sample surface acquired by the confocal microscope with high-resolution two-dimensional shape information acquired by the SEM.

A method of mounting a 4-segment reflection electron detector on the SEM is also known. Using such a method, a height of particles can be measured by calculating four SEM images and converting the images to three dimensions. Since the four SEM images are detected at once, it is not necessary to tilt the sample or align fields of view, and thus, it is possible to easily obtain three-dimensional information including particle height information.

### CITATION LIST

### Patent Literature

PTL 1: JP2010-80144A

### SUMMARY OF THE INVENTION

### Technical Problem

The combined analysis of particles in PTL 1 as described above is advantageous in that the coordinate systems of the confocal microscope and the SEM are shared, and thus, the respective fields of view can be precisely aligned. However, a resolution of the confocal microscope in a height direction is generally about 10 nm. Therefore, height measurement accuracy may be insufficient. For example, when a sample such as a microparticle having rapidly changing irregularities is set as a measurement target, reflected light may be scattered and the height measurement accuracy may become further insufficient.

Therefore, the technology of PTL 1 may have difficulty in measuring the height of particles with high accuracy. When measuring the height using the above-described 4-segment reflection electron detector, regarding a sample such as a particle having a steep slope, it may be difficult to capture reflection electrons generated from the slope part due to restriction in a capturing angle of the detector. Therefore, even when the 4-segment reflection electron detector is used, it may be difficult to measure the height of particles with high accuracy.

The present invention has been made in view of the above situation, and an object of the invention is to provide an analysis system and a particle analysis method capable of measuring a height of particles with high accuracy.

The above and other objects and new features of the present invention will be described with reference to the description of the specification and the accompanying drawings.

### Solution to Problem

A brief overview of a representative embodiment of the invention disclosed in the present application will be given as follows.

An analysis system according to a representative embodiment includes: an SEM apparatus that captures an image of each particle contained in a sample as an SEM image and observes a two-dimensional shape of each particle included in the SEM image; a CSI apparatus that captures an image of each particle contained in the sample as a CSI image and measures a height of each particle included in the CSI image; and a controller that controls the SEM apparatus and the CSI apparatus. The controller captures the SEM image using the SEM apparatus, classifies each particle included in the SEM image by size determined based on an imaging magnification of the CSI apparatus, and captures the CSI image of each particle in the particle group using the CSI apparatus for each classified particle group.

### ADVANTAGEOUS EFFECTS OF INVENTION

A brief overview of the effects obtained by the representative embodiment of the invention disclosed in the present application is that it becomes possible to measure a height of particles with high accuracy.

### BRIEF DESCRIPTION OF DRAWINGS

FIG. 1 is a schematic diagram illustrating an example of a configuration of an analysis system according to Embodiment 1.

FIG. 2 is a schematic diagram illustrating an example of a configuration of an SEM apparatus in FIG. 1.

FIG. 3 is a schematic diagram illustrating an example of a configuration of a CSI apparatus in FIG. 1.

FIG. 4A is a flowchart showing an example of an analysis method using the analysis system in FIG. 1.

FIG. 4B is a flowchart subsequent to FIG. 4A.

FIG. 5 is a plan view illustrating an example of a structure of a sample mount on which a sample is placed in FIG. 2.

FIG. 6 is a schematic diagram illustrating an example of a configuration of a group setting table used for classifying into particle groups in FIG. 4A.

FIG. 7 is a diagram illustrating an example of information of each particle obtained from the SEM apparatus and a result of classifying into particle groups in FIG. 4A.

FIG. 8 is a diagram illustrating an example of a state where a CSI image is captured using the CSI apparatus in FIG. 4B.

FIG. 9 is a schematic diagram illustrating an example of a configuration of an analysis system as a modification example of FIG. 1.

FIG. 10 is a flowchart showing an example of a method for verifying consistency of particles in a CSI image and an SEM image in an analysis system according to Embodiment 2.

FIG. 11A is a schematic diagram for explaining an example of specific processing contents in Step S302 in FIG. 10.

FIG. 11B is a schematic diagram for explaining an example of specific processing contents in Steps S303 and S304 in FIG. 10.

FIG. 11C is a schematic diagram for explaining another example of specific processing contents in Steps S303 and S304 in FIG. 10.

FIG. 12 is a flowchart showing an example of a method for verifying consistency of particles in a CSI image and an SEM image in an analysis system according to Embodiment 3.

FIG. 13A is a schematic diagram for explaining an example of specific processing contents in Steps S402 and S403 in FIG. 12.

FIG. 13B is a schematic diagram for explaining an example of specific processing contents in Steps S404 and S405 in FIG. 12.

### DESCRIPTION OF EMBODIMENTS

Hereinafter, embodiments of the present invention will be described in detail with reference to the drawings. Note that in all the drawings for explaining the embodiments, the same members are basically represented by the same reference numerals and signs, and descriptions thereof will not be repeated.

### Embodiment 1

### <Configuration of Analysis System>

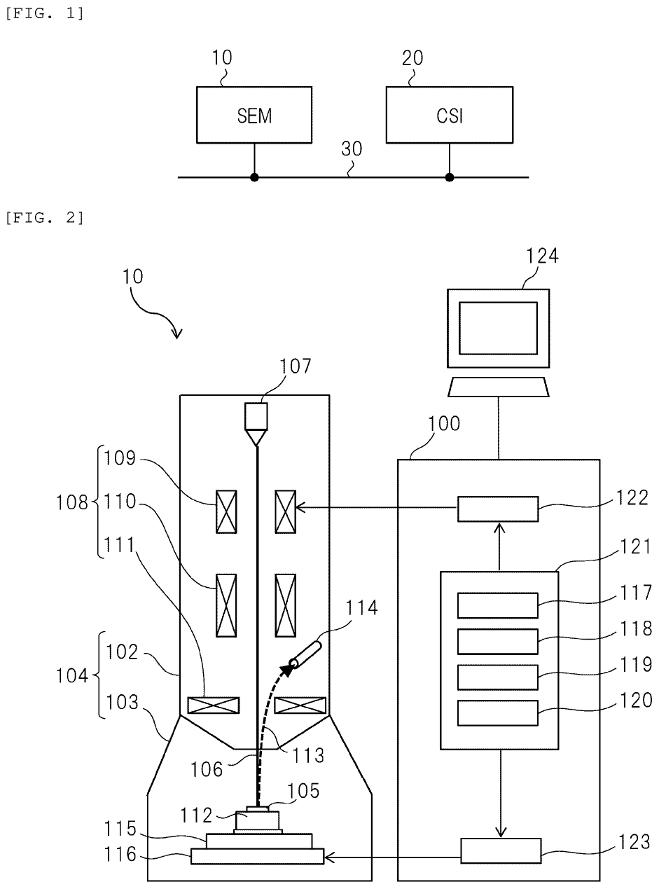

FIG. 1 is a schematic diagram illustrating an example of a configuration of an analysis system according to Embodiment 1. The analysis system illustrated in FIG. 1 includes an electron microscope (SEM apparatus) 10, a scanning white-light interference microscope (CSI apparatus) 20, and a communication network 30 connecting the microscopes. The communication network 30 establishes a wired or wireless communication path between the SEM apparatus 10 and the CSI apparatus 20. The communication network 30 is mainly used for transferring data between the apparatuses. Therefore, in the analysis system, a method of transferring data via, for example, a removable external storage medium may be applied instead of the communication network 30.

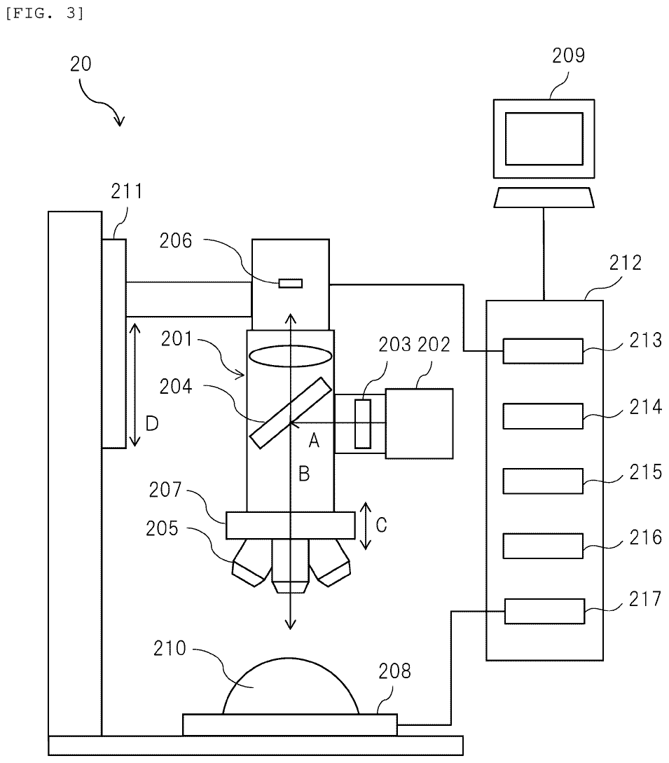

FIG. 2 is a schematic diagram illustrating an example of a configuration of the SEM apparatus 10 in FIG. 1. The SEM apparatus 10 includes an apparatus body 104 and a controller 100. The apparatus body 104 is configured by integrating a lens barrel 102 and a sample chamber 103. The apparatus body 104 functions as an imaging section that captures an SEM image of a measurement target while a sample 105 such as a filter that collects particles is set as the measurement target. The controller 100 includes a data calculation section 121, an optical system control section 122, a stage control section 123, and a display device 124, and controls the entire SEM apparatus 10.

The lens barrel 102 includes an electron gun 107 and an electron optical system 108. The electron gun 107 emits an electron beam 106. The electron optical system 108 controls a trajectory of the electron beam 106. The electron optical system 108 includes a condenser lens 109, a deflector 110, and an objective lens 111. The condenser lens 109 condenses the electron beam 106 emitted from the electron gun 107. The deflector 110 scans the electron beam 106. The objective lens 111 condenses the electron beam 106 to bring a surface of the sample 105 into focus.

When the sample 105 is irradiated with the electron beam 106, a signal 113 such as secondary electrons, reflection electrons, and characteristic X-rays is generated from the sample 105. A signal detector 114 is disposed at an appropriate position in the lens barrel 102 or in the sample chamber 103, and detects the signal 113. Specifically, the signal detector 114 includes an electron detector that detects secondary electrons and reflection electrons, and an X-ray detector that detects characteristic X-rays such as an energy dispersive X-ray spectrometry (EDX) detector.

The sample chamber 103 has a structure in which a sample mount 112 is accommodated via an inlet/outlet port (not illustrated in the drawing) that can be opened and closed. The sample 105 is placed on the sample mount 112. The sample chamber 103 further includes a sample stage 115 on which the sample mount 112 is placed. The sample stage 115 includes a stage control device 116. The stage control device 116 displaces position and orientation of the sample 105 in the sample chamber 103 by moving or rotating the sample 105 in the sample chamber 103, for example, in a direction of a horizontal plane or in a direction perpendicular to the plane.

The stage control device 123 controls the stage control device 116. The optical system control device 122 controls the electron optical system 108. The stage control device 123 and the optical system control device 122 are implemented by hardware circuits such as an application specific integrated circuit (ASIC) or a field programmable gate array (FPGA). The SEM apparatus 10 irradiates the sample 105 with the electron beam 106 at a freely selected position by moving the sample stage 115 or controlling the deflector 110. The SEM apparatus 10 detects the signal 113 from the sample 105 using the signal detector 114, thereby allowing the sample 105 to be observed at freely selected position and magnification.

The data calculation section 121 is configured with, for example, an information processing device such as a computer. The data calculation section 121 includes an image acquisition section 117, an instruction input section 118, a data storage section 119, and a signal processing section 120. The data storage section 119 is configured with, for example, a combination of volatile memories and non-volatile memories. The image acquisition section 117, the instruction input section 118, and the signal processing section 120 are implemented by, for example, processors executing programs stored in the data storage section 119 or the like.

The instruction input section 118 receives various instructions from a user via a keyboard, a mouse, a communication network 30, or the like. £ The image acquisition section 117 converts the signal 113 detected by the signal detector 114 such as secondary electrons and reflection electrons into SEM image data. For example, the signal processing section 120 performs specifying of the position of each particle included in the SEM image, observation of the two-dimensional shape of each particle, and the like based on the SEM image data converted by the image acquisition section 117. The signal processing section 120 also performs elemental analysis of each particle and the like based on the detection result of the signal detector 114, specifically the X-ray detector.

The data calculation section 121 performs various calculations necessary for control of the apparatus body 104 based on instruction information input to the instruction input section 118, information stored in the data storage section 119, and the like. The stage control section 123 and the optical system control section 122 control the stage control section 116 and the electron optical system 108, respectively, based on results of the calculations performed by the data calculation section 121. The display device 124 is a screen display device such as a display device, and displays the SEM image of the sample 105 acquired by the image acquisition section 117 on a screen.

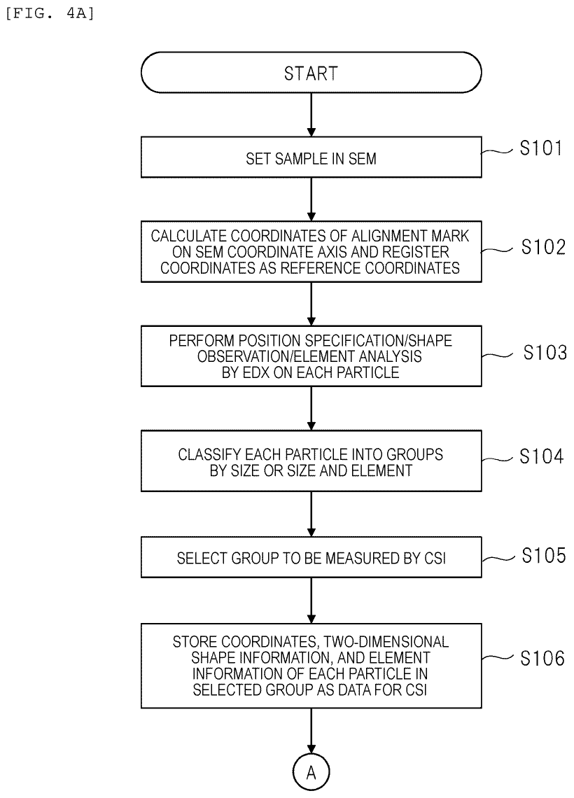

FIG. 3 is a schematic diagram illustrating an example of a configuration of the CSI apparatus 20 in FIG. 1. The CSI apparatus 20 illustrated in FIG. 3 includes an apparatus body 201, a sample stage 208 on which a sample 210 to be measured is placed, and a controller 212. The controller 212 controls the entire CSI apparatus 20, and processes obtained CSI image data as one of such control. The sample 210 is, for example, a filter that collects particles. The apparatus body 201 includes a white-light source 202, a filter 203, a beam splitter 204, a revolver-type two-beam interference objective lens group 205 that can change magnification, a camera 206, and a piezo actuator 207 or an electric motor 211 that moves the two-beam interference objective lens group 205 in a Z-axis direction.

The controller 212 includes an image acquisition section 213, an instruction input section 214, a data storage section 215, a data calculation section 216, and a stage control section 217. The image acquisition section 213, the instruction input section 214, the data storage section 215, and the data calculation section 216 are, for example, configured by an information processing device such as a computer. The data storage section 215 is configured with, for example, a combination of volatile memories and non-volatile memories. The image acquisition section 213, the instruction input section 214, and the data calculation section 216 are implemented, for example, by processors executing programs stored in the data storage section 215 or the like. The stage control section 217 is implemented, for example, by a hardware circuit such as an ASIC or an FPGA.

The instruction input section 214 receives various instructions from a user via a keyboard, a mouse, the communication network 30, or the like. The image acquisition section 213 acquires CSI image data captured by the camera 206. The data calculation section 216 calculates a three-dimensional shape of the sample 210 using information input to the instruction input section 214 and CSI image data acquired by the image acquisition section 213, and stores a calculation result in the data storage section 215. The stage control section 217 controls a position of the sample stage 208. A display device 209 is a screen display device such as a display device, and displays, for example, the CSI image of the sample 210 obtained by the data calculation section 216 such as a three-dimensional shape on a screen.

As indicated by an arrow A, light (white light) emitted from the white-light source 202 passes through a filter (such as a wavelength filter or a polarizing filter) 203, and then is guided by a beam splitter 204 to the two-beam interference objective lens group 205 (arrow B). An internal beam splitter (not illustrated in the drawing) in the two-beam interference objective lens group 205 splits the light into two beams of a first beam directed toward the measurement target including the sample 210 itself and substances therein, and a second beam directed toward a reference mirror (not illustrated in the drawing).

Here, the measurement signal can be observed in a form of an interference signal between two beams when an optical distance from the internal beam splitter to the measurement target object is equal to an optical distance from the internal beam splitter to the reference mirror, in which the internal beam splitter is provided in the two-beam interference objective lens group 205 disposed opposite the measurement target object. The camera 206 captures the interference signal, that is, an interference fringe (interference pattern), as the CSI image, and the image acquisition section 213 acquires the CSI image data. The data calculation section 216 converts the CSI image data including the interference signal into three-dimensional shape information and stores the information in the data storage section 215.

In the configuration example illustrated in FIG. 3, a height position of the two-beam objective lens group 205 is scanned (movement of an arrow C) using the piezo actuator 207 while a distance from the internal beam splitter to the reference mirror (not illustrated in the drawing) is fixed, thereby changing a distance between the internal beam splitter and the measurement target object. When it is necessary to change the height position of the two-beam interference objective lens group 205 over a long distance according to the shape of the measurement target object, the electric motor 211 can be used to change the distance to the measurement target object (movement of an arrow D). The CSI apparatus 20 uses a white-light source with a short coherence length (coherence length of 1 μm or less), and thus, the height position at which the interference signal is obtained is a Z position (depth position) of the measurement target object.

### <Operation of Analysis System>

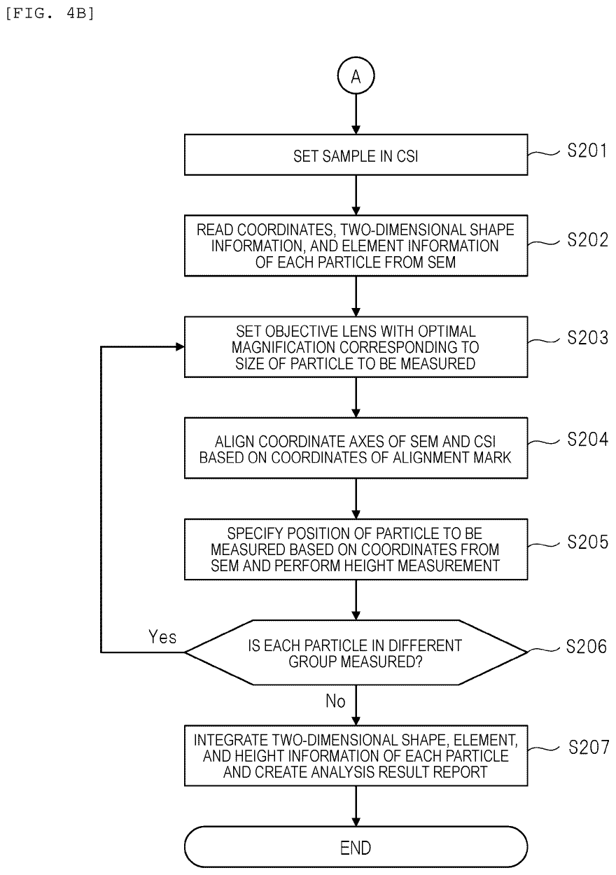

FIG. 4A is a flowchart showing an example of an analysis method using the analysis system in FIG. 1. FIG. 4B is a flowchart subsequent to FIG. 4A. In FIG. 4A, first, a user or a transport device places the sample 105 such as a filter that collects particles on the sample mount 112 of the SEM apparatus 10, and places the sample mount 112 on the sample stage 115 (Step S101).

Subsequently, the controller 100 uses the SEM apparatus 10 to capture, for example, an image of the sample mount 112 on which the sample 105 is placed. Then, the controller 100, specifically the data calculation section 121 calculates coordinates of two or more alignment marks provided on the sample mount 112 as coordinates of a reference position, and registers the coordinates of the reference position as reference coordinates in the data storage section 119 (Step S102). Note that the reference coordinates are not limited to the coordinates of the alignment marks, and may be, for example, coordinates of feature points or the like determined on the sample 105.

Next, in Step S103, the controller 100 causes the SEM apparatus 10 to capture an image of each particle contained in the sample 105 as a SEM image. Specifically, the SEM apparatus 10 irradiates the sample 105 with the electron beam 106 and captures an image of the sample 105 in a preset field of view to be observed. Here, the controller 100, specifically the data calculation section 121 regards a region having a contrast different from a contrast of a surrounding region by a predetermined threshold value or more in the SEM image as a particle. Then, observation of a two-dimensional shape of each particle and elemental analysis of each particle is performed. By observation of the shape of each particle, a size of each particle, specifically length, width, area, and perimeter, and the like of each particle are measured. Note that the processing of Step S103 may be performed before the processing of Step S102.

Next, in Step S104, the controller 100, specifically the data calculation section 121 classifies particles into particle groups by size based on results of particle shape observation in Step S103. For example, the data calculation section 121 sets each particle classified into a size in a first range in a first particle group, and sets each particle classified into a size in a second range in a second particle group. Here, a size range that serves as a reference for classification is determined based on imaging magnification of the CSI apparatus 20. The data calculation section 121 may classify particles by element based on results of elemental analysis of the particles in Step S103 in addition to classification by size. That is, for example, the data calculation section 121 may classify each particle included in the first particle group into more particle groups by element.

Subsequently, the controller 100, specifically the data calculation section 121 selects a particle group to be measured by the CSI apparatus 20 from the particle groups classified in Step S104 based on a user setting and the like (Step S105). Then, the data calculation section 121 stores coordinates, two-dimensional shape information, element information, and the like of each particle included in the selected particle group in the data storage section 119 as data for the CSI apparatus 20 (Step S106). The coordinates of each particle are, for example, relative coordinates of each particle with respect to a reference position (an alignment mark in the present embodiment) set as reference coordinates.

Subsequently, in FIG. 4B, the user or the transport device removes the sample mount 112 on which the sample 105 is placed from the SEM apparatus 10, and places the sample mount 112 on the sample stage 208 of the CSI apparatus 20 (Step S201). Thereby, the sample mount 112 is placed at a position of the sample 210 illustrated in FIG. 3. Next, the controller 212, specifically the data calculation section 216 reads the data for the CSI apparatus 20 stored in Step S106 in FIG. 4A into the data storage section 215 (Step S202). That is, relative coordinates regarding reference coordinates, two-dimensional shape information, element information, and the like of each particle in the particle group selected as the measurement target are read.

Subsequently, the controller 212 sets an objective lens having an optimal imaging magnification according to the size of the particle to be measured for the two-beam interference objective lens group 205 (Step S203). For example, when each particle in the first particle group described above is to be measured, an objective lens comprehensively determined for the first particle group is set. Next, the controller 212 aligns the SEM coordinate axis and the CSI coordinate axis based on the coordinates of the alignment marks (Step S204). Specifically, the controller 212 detects the alignment marks from the image acquired by the camera 206, and registers the coordinates of the alignment marks as the reference coordinates as in the SEM apparatus 10.

Next, in Step S205, the controller 212 specifies the position of the particle to be measured based on the coordinates of each particle read in Step S202, that is, the relative coordinates regarding the reference coordinates, and moves the sample stage 208 such that the position of the particle is positioned at a center of the image. Here, the controller 212 captures a CSI image using the camera 206 to perform height measurement of the particle positioned at the center of the CSI image, that is, three-dimensional shape measurement. For example, when the selected first particle group includes a plurality of particles, the controller 212 performs three-dimensional shape measurement of each particle while sequentially moving each particle to the center of the CSI image.

Then, the controller 212 determines whether another particle group is to be measured (Step S206). When another particle group is to be measured (Step S206: Yes), the controller 212 returns to Step S203 and repeats the processing of Steps S203 to S205 until no other particle group is to be measured. For example, when the second particle group is to be measured subsequently to the first particle group described above, in Step S203, an objective lens comprehensively determined for the second particle group is set.

Meanwhile, when no other particle group is to be measured (Step S206: No), the controller 212, specifically the data calculation section 216 integrates two-dimensional shape information, element information, and three-dimensional shape information of each particle to create an analysis result report (Step S207). Then, the controller 212 stores the created analysis result report in the data storage section 215 and also displays the report on the display device 209 or the like. The two-dimensional shape information and the element information of each particle are acquired from the SEM apparatus 10 in Step S202. The two-dimensional shape information includes length, width, area, perimeter, and the like. The three-dimensional shape information of each particle is acquired by the CSI apparatus 20 in Step S205. The three-dimensional shape information includes height, volume, and the like.

As described above, when the particle groups are determined based on the imaging magnification of the CSI apparatus 20, in FIG. 4B, the controller 212 uses the CSI apparatus 20 to first capture an image of each particle in the first particle group classified into a size in the first range at the first imaging magnification and measure a height of each imaged particle. Thereafter, the controller 212 captures an image of each particle in the second particle group classified into a size in the second range at the second imaging magnification and measure a height of each imaged particle. By such a procedure, it is possible to perform efficient analysis, and it is possible to perform highly accurate height measurement.

As a comparative example, it is assumed that the first particle group includes particles [1] and [2], the second particle group includes particles [3] and [4], and height measurement is performed in the order of the particle [1], the particle [3], the particle [4], and the particle [2]. Here, the objective lens in the two-beam interference objective lens section 205 may need to be switched between measurement of the particle [3] and measurement of the particle [2].

When the objective lens is switched, it is necessary to perform alignment again in Step S204, that is, to re-register the coordinates of the alignment marks. As a result, analysis efficiency may decrease. When alignment is performed again, for example, the same objective lens may be used in measurement of the particle [1] and measurement of the particle [2]. Even though, there is a risk that particle detection accuracy may vary due to positional error in alignment. When the objective lens is not switched, that is, when height measurement is performed at an inappropriate magnification, accuracy of height measurement, for example, resolution may decrease.

Meanwhile, as illustrated in FIG. 4B, when measurement is performed for each particle group according to the size, as the particles in the same particle group are measured sequentially, the height of each particle can be measured at an optimal magnification without performing the processing of Step S204, that is, alignment. As a result, analysis efficiency can be improved, and accuracy of height measurement can be improved. For example, particles that are too small to obtain sufficient measurement accuracy with the CSI apparatus 20 or particles that are too large to fit in the field of view of the CSI apparatus 20 can be excluded in advance from measurement targets of the CSI apparatus 20 in units of the particle group. Thereby, it is possible to improve analysis efficiency.

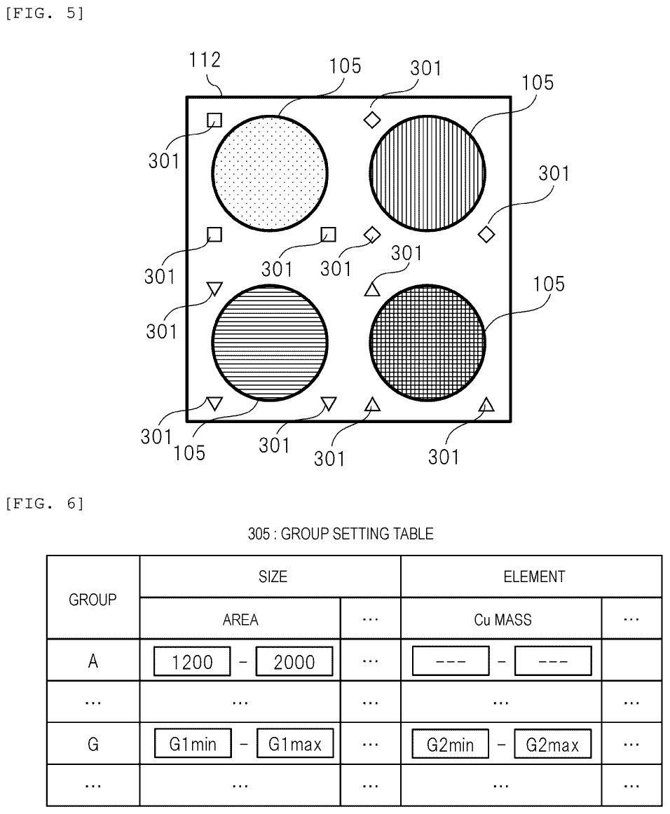

FIG. 5 is a plan view illustrating an example of a structure of the sample mount 112 on which the sample 105 is placed in FIG. 2. One or more samples 105 can be placed on the sample mount 112, in which each sample 105 has a large number of particles attached thereto. In the present example, a plurality of alignment marks 301, three alignment marks 301 in the present example, are provided at positions near each sample 105 on the sample mount 112. In FIG. 5, three alignment marks 301 are provided for each sample 105, but only three alignment marks 301 may be provided on the sample mount 112. The controller 100 may freely select an alignment mark in Step S102 in FIG. 4A. By narrowing a distance between alignment marks, alignment accuracy of the sample 105 placed inside the selected alignment mark can be improved.

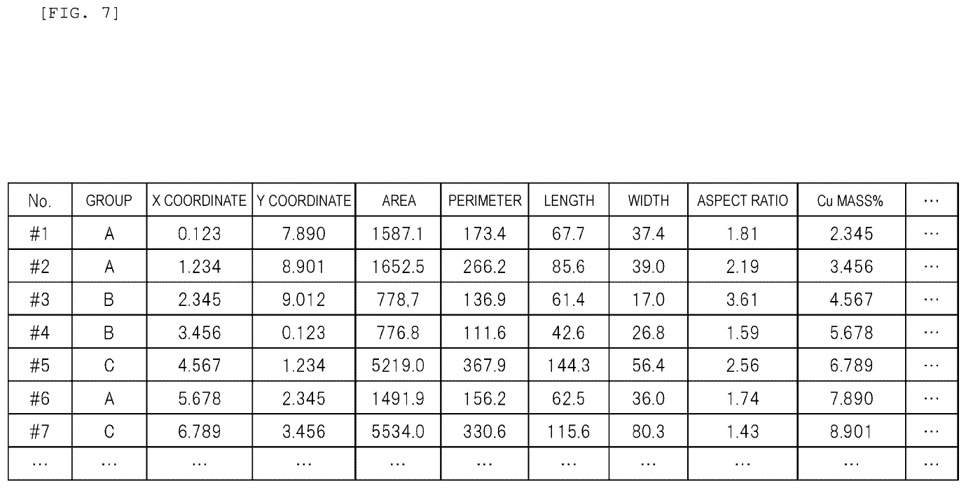

FIG. 6 is a schematic diagram illustrating an example of a configuration of a group setting table used for classifying into particle groups in FIG. 4A. A group setting table 305 illustrated in FIG. 6 is stored in, for example, the data storage section 119. The data calculation section 121 performs classification into particle groups based on the group setting table 305 in Step S104 in FIG. 4A. A user is able to freely set setting contents of the group setting table 305 via the instruction input section 118.

In the example illustrated in FIG. 6, when an area of a particle is in a range of 1200 to 2000, the particle is classified into a particle group A. When an area of a particle is in a range of G1min to G1max and a mass of copper (Cu) obtained from elemental analysis is in a range of G2min to G2max, the particle is classified into a particle group G. In the present example, the size serving as a reference for classification is the area, but the embodiment is not limited thereto. The size may be any of length, width, aspect ratio (=length/width), and perimeter, or may be a combination, for example, an AND condition of two or more of area, length, width, aspect ratio, and perimeter.

It is not necessary to explicitly classify all particles into particle groups. That is, particles not matching the conditions set in the group setting table 305 may be practically treated as a unmatching particle group. For example, a particle having a size difficult for the CSI apparatus 20 to measure can be classified into the unmatching particle group.

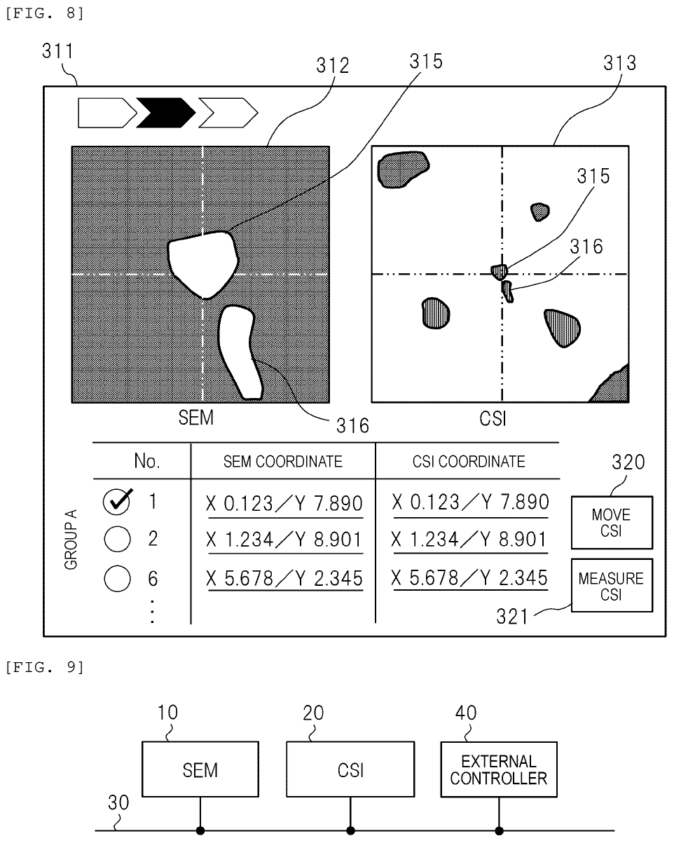

FIG. 7 is a diagram illustrating an example of information of each particle obtained from the SEM apparatus and a result of classifying into particle groups in FIG. 4A. Each particle is distinguished by automatically assigned numbers #1, #2, . . . , #7 . . . . Each particle is associated with position coordinates, that is, X and Y coordinates, two-dimensional shape information such as area, perimeter, length, width, and aspect ratio, and Cu mass as one of element information. The SEM apparatus 10 creates information as illustrated in FIG. 7 as a result of the processing of Step S103 in FIG. 4A. In the example illustrated in FIG. 7, particles are classified into three particle groups A, B, and C according to the area thereof by the processing of Step S104 in FIG. 4A.

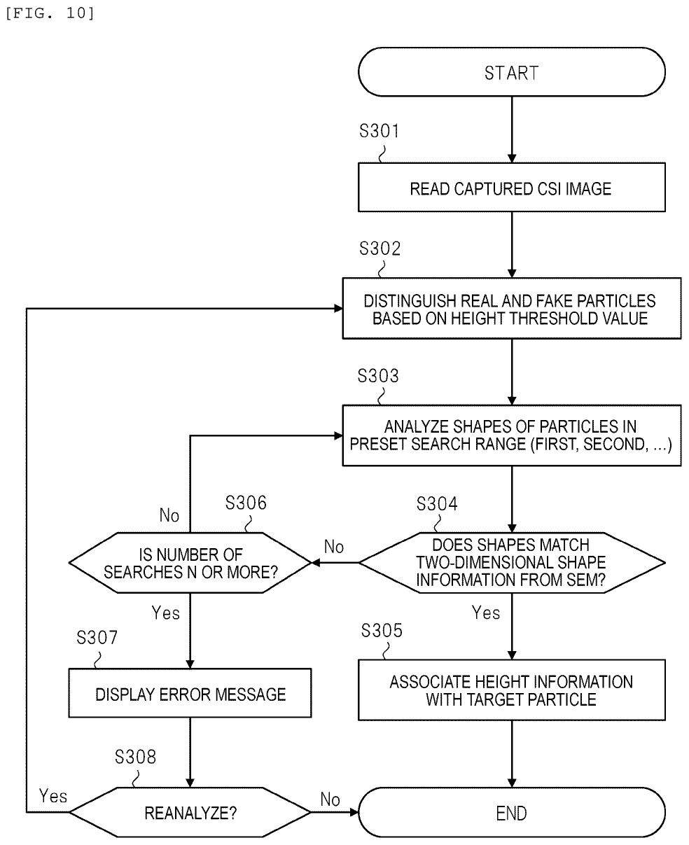

FIG. 8 is a diagram illustrating an example of a state where a CSI image is captured using the CSI apparatus in FIG. 4B. FIG. 8 shows an example of display contents on the display device 209 that follows capture of a CSI image. For example, in Step S205 in FIG. 4B, as illustrated in FIG. 8, while the sample stage 208 is moved such that a particle 315 to be measured is positioned at a center of a CSI image 313, capture of the CSI image 313 and height measurement of the particle 315 are performed. An amount of movement of the sample stage 208 is determined based on the coordinates of each particle acquired in Step S202.

In FIG. 8, when the particle 315 and a particle 316 are in the same particle group, subsequently, while the sample stage 208 is moved such that the particle 316 is positioned at the center of the CSI image 313, a height of the particle 316 is measured. Note that in the example illustrated in FIG. 8, a manual operation based on a user command is also possible. For example, a user is able to move the particle 315 having the number #1 in the particle group A to a center position of the CSI image 313 by pressing a CSI movement button 320 while the particle 315 is selected. Here, the user can also measure a height of the particle 315 by pressing a CSI measurement button 321. The SEM image 312 and the CSI image 313 of a certain particle 315 can be displayed on the display device 209, and the user can compare the two images.

### <Modification Example of Analysis System>

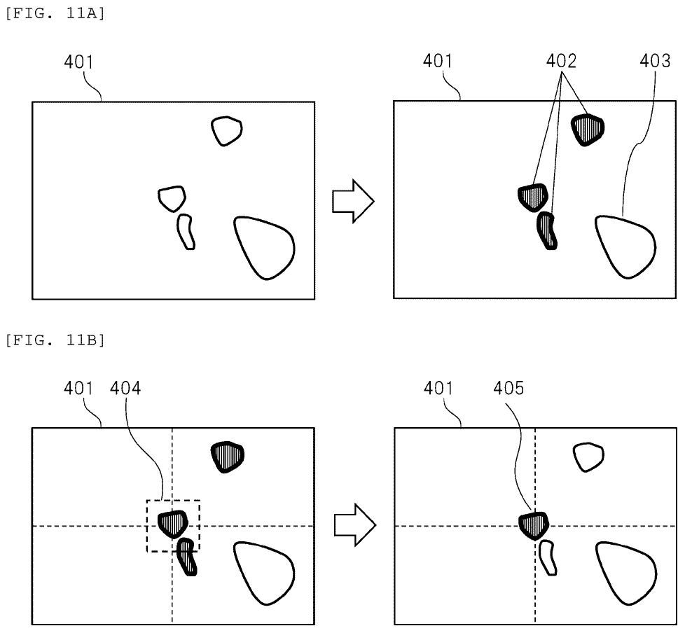

FIG. 9 is a schematic diagram illustrating an example of a configuration of an analysis system as a modification example of FIG. 1. The analysis system illustrated in FIG. 9 includes an external controller 40 in addition to the SEM apparatus 10 and the CSI apparatus 20 illustrated in FIG. 1. The external controller 40 is also connected to the communication network 30. The external controller 40 is, for example, an information processing device such as a computer including a processor, a memory, a user interface, a communication interface, and the like.

The external controller 40 performs, for example, association between the SEM apparatus 10 and the CSI apparatus 20, in other words, various kinds of processing for combined analysis. Specifically, the external controller 40 executes, for example, the processing of Steps S104 to S106 in FIG. 4A and the processing of Steps S202 and S207 in FIG. 4B based on programs stored in the memory via communication with the SEM apparatus 10 and communication with the CSI apparatus 20.

Note that such programs may be stored in a non-transitory computer readable recording medium and then supplied to the computer. Examples of such recording media include magnetic recording media such as hard disk drives, optical recording media such as digital versatile discs (DVDs) and Blu-ray discs, and semiconductor memories such as flash memories.

### <Main Effects of Embodiment 1>

As described above, using the method of Embodiment 1, combined analysis of the SEM apparatus 10 and the CSI apparatus 20, that is, a three-dimensional analysis is possible for the same particle, and a height of the particle can be measured with high accuracy. Specifically, using the CSI apparatus 20, the height can be measured with a high resolution of 0.1 nm or the like. Each particle imaged by the SEM apparatus 10 is classified by size determined based on the imaging magnification of the CSI apparatus 20. Thereby, it is possible to improve height measurement accuracy while improving analysis efficiency.

### Embodiment 2

### <Operation of Analysis System>

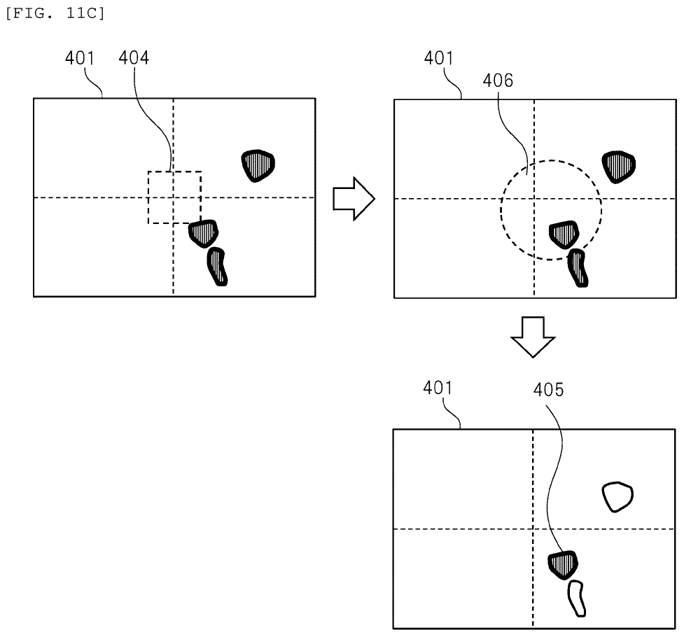

FIG. 10 is a flowchart showing an example of a method for verifying consistency of particles in a CSI image and an SEM image in an analysis system according to Embodiment 2. First, a problem as a premise is that, in practice, alignment deviations may occur in the SEM apparatus 10 and the CSI apparatus 20 due to accuracy of moving the sample stages 115 and 208. The imaging magnifications of the SEM apparatus 10 and the CSI apparatus 20 may differ. For example, the SEM apparatus 10 may have a high magnification and the CSI apparatus 20 may have a low magnification.

Therefore, in particular, when the CSI apparatus 20 captures an image of the sample 105 in which particles are densely packed, a particle may be erroneously recognized. As a specific example, in FIG. 8, the CSI image 313 should be captured with the particle 315 at the center, but the CSI apparatus 20 may erroneously capture the CSI image 313 with the particle 316 positioned near the particle 315 at the center. That is, erroneous recognition may occur in which the particle 315 in the SEM image 312 is associated with the particle 316 in the CSI image 313.

Here, the CSI apparatus 20 verifies consistency of each particle included in the CSI image and each particle included in the SEM image by additionally executing the flow illustrated in FIG. 10 in Step S205 in FIG. 4B. In FIG. 10, the controller 212, specifically the data calculation section 216 first reads the CSI image captured in Step S205 in FIG. 4B from the data storage section 215 with a certain particle as the measurement target (Step S301).

Then, the data calculation section 216 compares the height of the certain particle as the measurement target measured in Step S205 with a preset height threshold value to distinguish whether the particle is a real particle or a fake particle (Step S302). That is, in the SEM apparatus 10, whether the particle is real or fake is distinguished based on two-dimensional shape information. Therefore, a particle that has a low height and is originally a non-particle can be regarded as a particle. Here, by performing the processing of Step S302, it is possible to distinguish particles higher than the threshold value as real particles and particles lower than the threshold value as fake particles. Note that a user is able to preset the height threshold value via the instruction input section 214.

Then, using any one of a plurality of preset search ranges, the data calculation section 216 analyzes the two-dimensional shape of the particle included in a certain search range in the CSI image read in Step S301 (Step S303). For example, a first search range is set to a region one size larger than a target particle. Considering a case where the target particle is not within the first search range, a plurality of search ranges such as second and third search ranges are also set.

For example, the second search range is a range one size larger than the first search range, or a range shifted by a certain distance from the first search range. The third search range is a range different from the first search range and the second search range. A user is able to appropriately specify a method of defining the second search range, the third search range, and the like.

Using such a plurality of search ranges, the data calculation section 216 first analyzes the two-dimensional shape of a real particle included in the first search range using the first search range (Step S303). Then, the data calculation section 216 determines whether the two-dimensional shape of the real particle obtained by analysis substantially matches the two-dimensional shape information obtained from the SEM apparatus 10 associated with the particle (Step S304). Specifically, the data calculation section 216 determines whether a difference between the two-dimensional shape of the true particle obtained by analysis and the two-dimensional shape based on the two-dimensional shape information obtained from the SEM apparatus 10 is within a predetermined error range.

Here, when the two-dimensional shapes match each other (Step S304: Yes), the data calculation section 216 associates height information measured in Step S205 with the target particle (Step S305). Meanwhile, when the two-dimensional shapes do not match each other (Step S304: No), the data calculation section 216 goes through Step S306 to return to Step S303, changes the search range from the first search range to the second search range, and performs the same processing. Here, for example, when a particle having a matching two-dimensional shape is detected in the second search range, the data calculation section 216 may extract the height information of the particle from the CSI image, and associate the particle having the matching two-dimensional shape with the height information.

In Step S306, the data calculation section 216 determines whether the number of searches reached a preset number (N). When the number did not reach the preset number (Step S306: No), the processing returns to Step S303. Accordingly, when the two-dimensional shapes do not match each other in Step S304, the data calculation section 216 searches for a real particle having a matching two-dimensional shape while sequentially changing the search range to first, second, third,. until the number of searches reaches the preset number (N).

Meanwhile, when the number of searches reached the preset number (N) (Step S306: Yes), the data calculation section 216 displays an error message (Step S307) and, for example, prompts a user to determine whether to set the height threshold value again and continue analysis (Step S308). When reanalysis is to be performed (Step S308: Yes), the data calculation section 216 returns to Step S302 using a height threshold value newly set and repeats the same processing. By repeating such a flow for all particles to be measured, correct height information is associated with all particles to be measured in addition to two-dimensional shape information and element information as illustrated in FIG. 7.

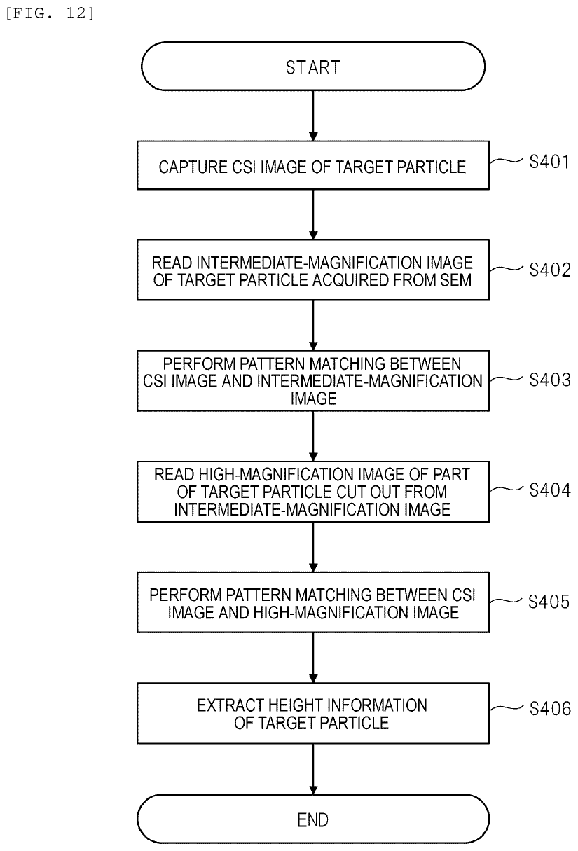

FIG. 11A is a schematic diagram for explaining an example of specific processing contents in Step S302 in FIG. 10. In FIG. 11A, a CSI image 401 read in Step S301 may include real particles 402 and a fake particle 403. The data calculation section 216 distinguishes particles with heights equal to or greater than a threshold value set by the user as the real particles 402 and a particle with a height less than the threshold value as the fake particle 403.

FIG. 11B is a schematic diagram for explaining an example of specific processing contents in Steps S303 and S304 in FIG. 10. The data calculation section 216 sets a first search range 404 in the CSI image 401 and analyzes two-dimensional shapes of the real particles included in the first search range 404. The first search range 404 is preset such that a center thereof is equal to a center of the CSI image 401 and a size thereof is one size larger than the target particle.

In the present example, the two-dimensional shapes of the real particles included in the first search range 404 matches the two-dimensional shape information obtained from the SEM apparatus 10 corresponding to the particle. Such a state corresponds to a state in which no positional deviation occurred when the CSI apparatus 20 moved the sample stage 208 based on the coordinates of the particle obtained from the SEM apparatus 10. As such, when consistency of the particle is confirmed, the data calculation section 216 associates the two-dimensional shape information obtained from the SEM apparatus 10 with a real particle 405 having the matching two-dimensional shape.

FIG. 11C is a schematic diagram for explaining another example of specific processing contents in Steps S303 and S304 in FIG. 10. In the example illustrated in FIG. 11C, compared to FIG. 11B, the real particle is not within the first search range 404. Such a state corresponds to a state where a positional deviation, for example, a certain amount of offset occurred when the CSI apparatus 20 moved the sample stage 208 based on the coordinates of the particle obtained from the SEM apparatus 10.

Here, the data calculation section 216 changes the search range and analyzes the two-dimensional shape of the real particle included in a second search range 406. In the present example, the two-dimensional shape of the real particle is not included in the first search range 404 but is included in the second search range 406, in which the two-dimensional shape of the real particle matches the two-dimensional shape information obtained from the SEM apparatus 10. As such, when consistency of the particle is confirmed, the data calculation section 216 associates the two-dimensional shape information obtained from the SEM apparatus 10 with the real particle 405 having the matching two-dimensional shape.

Note that, although a case where the positional deviation occurs is exemplified herein, a state where the real particle is not in the first search range 404 may occur even when the particle is distinguished as a fake particle. Then, even when the search range is changed to the second search range 406, consistency of the particle is not confirmed. Here, for example, the data calculation section 216 may return to Step S302 in FIG. 10 and change the height threshold value, or may skip the particle currently being verified and execute the flow illustrated in FIG. 10 on the next particle as a verification target.

In the above description, a case where the data calculation section 216 in the CSI apparatus 20 executes the flow illustrated in FIG. 10 is exemplified. However, the present invention is not limited thereto, and the external controller 40 illustrated in FIG. 9 may execute the flow illustrated in FIG. 10. That is, the external controller 40 is able to execute the flow illustrated in FIG. 10 by acquiring the two-dimensional shape information of each particle from the SEM apparatus 10 and acquiring the CSI image and the height information of each particle from the CSI apparatus 20.

### <Main Effects of Embodiment 2>

As described above, using the method of Embodiment 2, the same effects as those described in Embodiment 1 can be obtained. Each particle is distinguished as a real particle or a fake particle based on height information. Thereby, it is possible to obtain analysis results on real particles only, that is, analysis result reports in Step S207 in FIG. 4B. The two-dimensional shape of each particle included in the CSI image is compared with the two-dimensional shape information obtained from the SEM image to verify consistency of each particle. Thereby, it is possible to prevent erroneous recognition of particles due to positional deviation during alignment and the like.

### Embodiment 3

### <Operation of Analysis System>

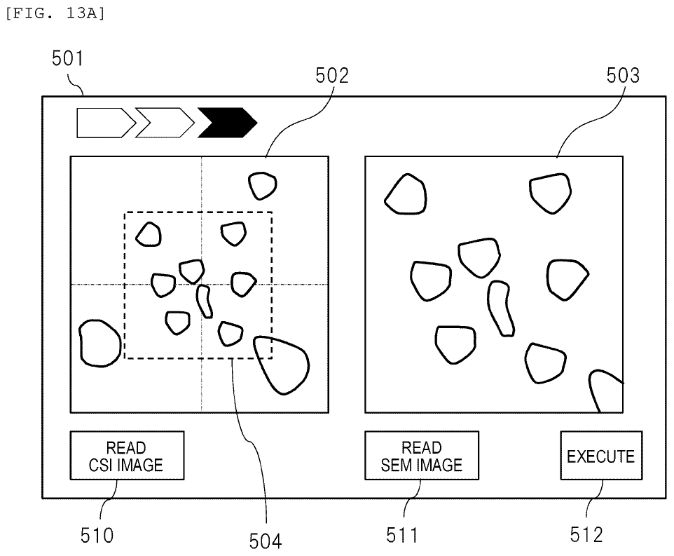

FIG. 12 is a flowchart showing an example of a method for verifying consistency of particles in a CSI image and an SEM image in an analysis system according to Embodiment 3. In particular, when a large number of particles are densely packed or when a plurality of particles are extremely similar in the two-dimensional shape information, the flow illustrated in FIG. 10 may not be able to sufficiently verify consistency of the particles.

Therefore, using the flow illustrated in FIG. 12 instead of the flow illustrated in FIG. 10, it is also possible to verify consistency of a target particle based on arrangement relationship between the target particle and each particle near the target particle. The flow illustrated in FIG. 12 is additionally executed, for example, in Step S205 in FIG. 4B.

In FIG. 12, the controller 212, specifically the data calculation section 216 first captures a CSI image of a certain target particle as a measurement target (Step S401). The data calculation section 216 reads an SEM image (an intermediate-magnification image in the present embodiment) captured in Step S103 in FIG. 4A from the data storage section 119 with the target particle as a measurement target (Step S402). The intermediate-magnification image is, for example, an SEM image acquired in a field of view wider than the size of the target particle.

Subsequently, the data calculation section 216 performs pattern matching between the CSI image and the intermediate-magnification image (Step S403). For example, the data calculation section 216 sets the intermediate-magnification image as a template image, calculates a degree of matching with the CSI image, and extracts a part having the highest degree of matching from the CSI image. Then, the data calculation section 216 narrows a detection range of the target particle from the entire range of the CSI image to a search range based on the result of pattern matching between the CSI image and the intermediate-magnification image.

Next, the data calculation section 216 reads an image obtained by cutting out only a region of the target particle from the intermediate-magnification image as the SEM image or an SEM image captured at a high magnification in Step S103 (Step S404) as a high-magnification image. Subsequently, the data calculation section 216 detects a particle having a high degree of matching as a target particle by performing pattern matching on the search range between the CSI image and the high-magnification image (Step S405). Then, the data calculation section 216 extracts height information of the detected target particle (Step S406).

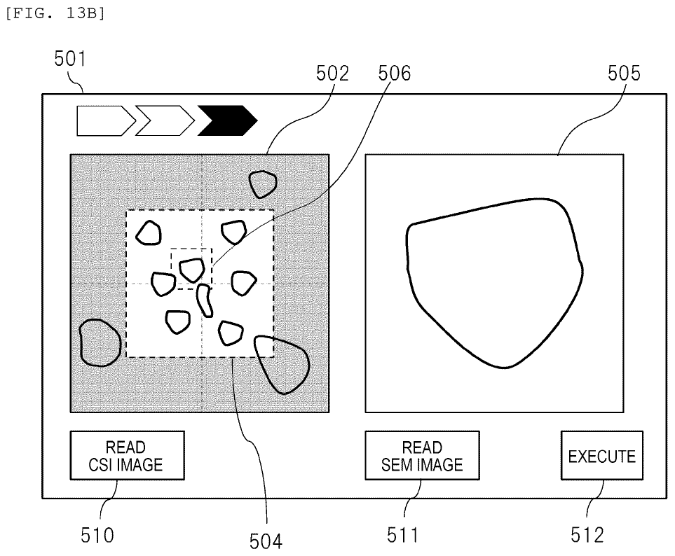

FIG. 13A is a schematic diagram for explaining an example of specific processing contents in Steps S402 and S403 in FIG. 12. FIG. 13A shows, for example, an example of a display screen 501 displayed on the display device 209 of the CSI apparatus 20. In the present example, a user is able to display a CSI image 502 on the display screen 501 by pressing a CSI image reading button 510. Similarly, the user is able to display an SEM image (an intermediate-magnification image 503 in the present example) on the display screen 501 by pressing an SEM image reading button 511. Then, when the user presses an executing button 512, pattern matching is executed.

The data calculation section 216 reads the CSI image 502 captured in Step S401 with the target particle as the measurement target, and the SEM image (an intermediate-magnification image 503 in the present example) captured in Step S103 in FIG. 4A with the target particle as the measurement target. Then, in FIG. 13A, the data calculation section 216 performs pattern matching between the CSI image 502 and the intermediate-magnification image 503. When the intermediate-magnification image 503 is used as a template image, the data calculation section 216 extracts a region having the highest degree of matching from the CSI image 502 and narrows a detection range of the target particle from the entire range of the CSI image 502 to a search range 504.

FIG. 13B is a schematic diagram for explaining an example of specific processing contents in Steps S404 and S405 in FIG. 12. FIG. 13B also shows the display screen 501 similar to that in FIG. 13A. The data calculation section 216 reads an image obtained by cutting out only a region of the target particle from the intermediate-magnification image or an SEM image captured at high magnification in Step S103 as a high-magnification image 505.

Then, the data calculation section 216 detects a particle 506 having a high degree of matching as a target particle by performing pattern matching on the search range 504 in the CSI image 502 using the high-magnification image 505 as a template image. The data calculation section 216 extracts the height of the detected target particle from data measured using the CSI apparatus 20, and associates the target particle with two-dimensional shape information obtained from the SEM apparatus 10.

Note that, in the above description, the data calculation section 216 in the CSI apparatus 20 executes the flow illustrated in FIG. 12 as an example. However, the present invention is not limited thereto, and the external controller 40 illustrated in FIG. 9 may execute the flow illustrated in FIG. 12. That is, the external controller 40 is able to execute the flow illustrated in FIG. 12 by acquiring the SEM image of each particle from the SEM apparatus 10 and the CSI image of each particle from the CSI apparatus 20.

### <Main Effects of Embodiment 3>

As described above, using the method of Embodiment 3, the same effects as those described in Embodiment 2 can be obtained. Even in a state where it is difficult to verify consistency of particles by the method of Embodiment 2, consistency of particles may be sufficiently verified using the method of Embodiment 3.

As described above, the present invention proposed by the present inventors is specifically described based on the above-described embodiments. However, the present invention is not limited to the above-described embodiments and can be modified in various forms without departing from the gist of the present invention. For example, the above-described embodiments are described in detail to make the present invention easier to understand, and are not necessarily limited to those having all of the configurations described. It is possible to replace a part of a configuration of a certain embodiment with a configuration of another embodiment, and it is also possible to add a configuration of another embodiment to a configuration of a certain embodiment. It is possible to add, remove, or replace other configurations with respect to a part of a configuration of each embodiment.

### REFERENCE SIGNS LIST

10: electron microscope (SEM apparatus)
100: controller
102: lens barrel
103: sample chamber
104: apparatus body
105: sample
106: electron beam
107: electron gun
108: electron optical system
109: condenser lens
110: deflector
111: objective lens
112: sample mount
113: signal
114: signal detector
115: sample stage
116: stage control device
117: image acquisition section
118: instruction input section
119: data storage section
120: signal processing section
121: data calculation section
122: optical system control section
123: stage control section
124: display device
20: scanning white-light interference microscope (CSI apparatus)
201: apparatus body
202: white-light source (light source)
203: filter
204: beam splitter
205: two-beam interference objective lens group
206: camera
207: piezo actuator
208: sample stage
209: display device
210: sample
211: electric motor
212: controller
213: image acquisition section
214: instruction input section
215: data storage section
216: data calculation section
217: stage control section
30: communication network
301: alignment mark
305: group setting table
312: SEM image
313: CSI image
315, 316: particle
40: external controller
401: CSI image
402: real particle
403: fake particle

1. An analysis system comprising:
a scanning electron microscope (SEM) apparatus that captures an image of each particle contained in a sample as an SEM image and observes a two-dimensional shape of each particle included in the SEM image;
a coherence scanning interferometry (CSI) apparatus that captures an image of each particle contained in the sample as a CSI image and measures a height of each particle included in the CSI image; and
a controller that controls the SEM apparatus and the CSI apparatus, wherein
the controller captures the SEM image using the SEM apparatus, classifies each particle included in the SEM image by size determined based on an imaging magnification of the CSI apparatus, and captures the CSI image of each particle in the particle group using the CSI apparatus for each classified particle group.

2. The analysis system according to claim 1, wherein
the controller uses the CSI apparatus to
capture an image of each particle in a first particle group classified into a size in a first range at a first imaging magnification and measure a height of each captured particle, and
then capture an image of each particle in a second particle group classified into a size in a second range at a second imaging magnification and measure a height of each imaged particle.

3. The analysis system according to claim 1, wherein
the controller calculates relative coordinates of each particle included in the SEM image regarding reference coordinates of a reference position provided on the sample or a sample mount on which the sample is placed using the SEM apparatus and captures the CSI image using the CSI apparatus based on the calculated relative coordinates.

4. The analysis system according to claim 3, wherein
the controller acquires two-dimensional shape information of each particle included in the SEM image and verifies consistency of each particle included in the CSI image and each particle included in the SEM image by comparing two-dimensional shape of each particle included in the CSI image with the two-dimensional shape information acquired from the SEM image.

5. The analysis system according to claim 3, wherein
the controller verifies consistency of each particle included in the CSI image and each particle included in the SEM image by performing pattern matching between the CSI image and the SEM image.

6. The analysis system according to claim 1, wherein
the SEM apparatus further analyzes elements of each particle included in the SEM image, and
the controller classifies each particle included in the SEM image by element in addition to size.

7. The analysis system according to claim 1, wherein
the controller distinguishes whether each particle is a real particle or a fake particle by comparing a height of each particle measured by the CSI apparatus with a preset height threshold value.

8. A particle analysis method using a scanning electron microscope (SEM) apparatus that captures an image of each particle contained in a sample as an SEM image and observes a two-dimensional shape of each particle included in the SEM image and a coherence scanning interferometry (CSI) apparatus that captures an image of each particle contained in the sample as a CSI image and measures a height of each particle included in the CSI image, the method comprising:
capturing the SEM image using the SEM apparatus, classifying each particle included in the SEM image by size determined based on an imaging magnification of the CSI apparatus, and capturing the CSI image of each particle in the particle group using the CSI apparatus for each classified particle group.

9. The particle analysis method according to claim 8, further comprising:
using the CSI apparatus,
capturing an image of each particle in a first particle group classified into a size in a first range at a first imaging magnification and measuring a height of each imaged particle, and
then capturing an image of each particle in a second particle group classified into a size in a second range at a second imaging magnification and measuring a height of each imaged particle.

10. The particle analysis method according to claim 8, further comprising:
calculating relative coordinates of each particle included in the SEM image regarding reference coordinates of a reference position provided on the sample or a sample mount on which the sample is placed using the SEM apparatus and capturing the CSI image using the CSI apparatus based on the calculated relative coordinates.

11. The particle analysis method according to claim 10, further comprising:
acquiring two-dimensional shape information of each particle included in the SEM image and verifying consistency of each particle included in the CSI image and each particle included in the SEM image by comparing two-dimensional shape of each particle included in the CSI image with the two-dimensional shape information acquired from the SEM image.

12. The particle analysis method according to claim 10, further comprising:
verifying consistency of each particle included in the CSI image and each particle included in the SEM image by performing pattern matching between the CSI image and the SEM image.

13. The particle analysis method according to claim 8, wherein
the SEM apparatus further analyzes elements of each particle included in the SEM image, and
each particle included in the SEM image is classified by element in addition to size.

14. The particle analysis method according to claim 8, further comprising:
distinguishing whether each particle is a real particle or a fake particle by comparing a height of each particle measured by the CSI apparatus with a preset height threshold value.
